(19) United States
(12) Patent Application Publication
(10) Pub. No.: US 2026/0271627 A1
(43) Pub. Date: Sep. 10, 2026

(54) HIGHLY RELIABLE RESISTIVE MEMORY CELL AND METHODS OF FORMING THE SAME

(71) Applicant: Applied Materials, Inc., Santa Clara, CA (US)

(72) Inventors: Sundararaman NARAYANAN, Cupertino, CA (US); Pramod RAVINDRA, Boston, MA (US); Yufeng QIU, Schenectady, NY (US); Jee-Jay CHEN, Ballston Lake, NY (US)

(21) Appl. No.: 19/340,530

(22) Filed: Sep. 25, 2025

Related U.S. Application Data
(60) Provisional application No. 63/767,948, filed on Mar. 6, 2025.

(51) Int. Cl. H10N 70/00; H10B 63/00; H10N 70/20

(52) U.S. Cl. CPC H10N 70/063; H10B 63/80; H10N 70/026; H10N 70/24; H10N 70/8265; H10N 70/8833

(57) ABSTRACT

The present disclosure relates to a resistive memory device. Embodiments of the present disclosure include a resistive memory device. The resistive memory device includes a bottom via couple to a bottom electrode layer. The bottom electrode layer is disposed over a substrate. The bottom electrode layer includes TiN, TaN, Ru, or combinations thereof. The resistive memory device further includes a switching layer disposed over the bottom electrode layer, a TaOx oxygen exchange layer disposed over the switching layer, and a top electrode layer disposed over the TaOx oxygen exchange layer. The resistive memory device further includes an encapsulation layer disposed across the resistive memory device and the substrate. A top metal filled via coupled to the top electrode layer. The top metal filled via is formed thorough the encapsulation layer and the interlayer dielectric fill.

### CROSS-REFERENCE TO RELATED APPLICATIONS

This application claims priority to U.S. Provisional Patent Application Ser. No. 63/767,961, filed on Mar. 6, 2025, and to U.S. Provisional Patent Application Ser. No. 63/767,948, filed on Mar. 6, 2025, which herein are incorporated by reference.

### BACKGROUND

### Field

Embodiments described herein generally relate to nonvolatile memory cells, and more particularly, to systems and methods for forming and etching highly reliable resistive memory cells used in nonvolatile memory devices.

### Description of the Related Art

Nonvolatile memory cells are used in systems in which persistent storage is required. For example, digital cameras use nonvolatile memory cards to store images and digital music players use nonvolatile memory to store audio data. Nonvolatile memory is also used to persistently store data in computer environments.

Nonvolatile memory is often formed using electrically-erasable programmable read only memory (EPROM) technology. This type of nonvolatile memory contains floating gate transistors that can be selectively programmed or erased by application of suitable voltages to their terminals. As fabrication techniques improve, it is becoming possible to fabricate nonvolatile memory devices with increasingly smaller dimensions. However, as device dimensions shrink, scaling issues pose challenges for traditional nonvolatile memory technology, including resistive switching nonvolatile memory, sometimes referred to as resistive random access memory (ReRam).

Therefore, there is a need for highly reliable resistive memory cells and methods of forming the same.

### SUMMARY

Embodiments described herein generally relate to nonvolatile memory cells, and more particularly, to systems and methods for forming and etching highly reliable resistive memory cells used in nonvolatile memory devices.

Embodiments of the present disclosure include a method for preparing a resistive memory cell. The method includes forming a resistive memory cell stack. Forming the resistive memory cell stack further includes depositing a bottom electrode layer over a substrate. The bottom electrode layer includes TiN, TaN, Ru, or combinations thereof. A switching layer is deposited in contact with the bottom electrode layer in the presence of an oxygen containing gas. A TaOx oxygen exchange layer is deposited in contact with the switching layer. A top electrode layer is deposited over the TaOx oxygen exchange layer. The top electrode layer is in contact with the TaOx oxygen exchange layer. The method for preparing a resistive memory cell stack culminates with etching the resistive memory cell stack. The etching of the resistive memory cell stack includes performing an etching operation to form at least a portion of the resistive memory cell stack. The etching operation is performed through a patterned hardmask layer positioned over the top electrode layer. Oxidizing sidewalls of one or more layers within the resistive memory cell stack. The sidewalls are formed during the etching operation and forming an encapsulation layer over the at least a portion of the resistive memory cell.

Embodiments of the present disclosure further include a resistive memory device. The resistive memory device includes a bottom via couple to a bottom electrode layer. The bottom electrode layer is disposed over a substrate. The bottom electrode layer includes TiN, TaN, Ru, or combinations thereof. The resistive memory device further includes a switching layer disposed over the bottom electrode layer, a TaOx oxygen exchange layer disposed over the switching layer, and a top electrode layer disposed over the TaOx oxygen exchange layer. The resistive memory device further includes an encapsulation layer disposed over the top electrode layer. An interlayer dielectric fill disposed over the encapsulation layer and a top metal filled via coupled to the top electrode layer. The top metal filled via is formed thorough the encapsulation layer and the interlayer dielectric fill.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of a multi-chamber processing system according to one or more embodiments of the present disclosure.

FIG. 2A is a cross sectional view of a processing chamber, according to one or more embodiments.

FIG. 2B is an enlarged view of a portion of the processing chamber of FIG. 2A, according to one or more embodiments.

FIG. 3 is a cross sectional view of a processing chamber, according to one or more embodiments.

FIG. 4 depicts a process flow diagram of a method 400 for forming highly reliable resistive memory cells, according to one or more embodiments.

FIGS. 5A, 6A, 7A, 8A, 9A, 10A, 11A, 12A, 13A, 14A, 15A, 16A, and 17A depict schematic, cross-sectional views of the formation of a resistive memory cell, according to one or more embodiments.

FIG. 8AA, 9AA, and 10AA depict schematic, cross-sectional views of the formation of a resistive memory cell, according to one or more embodiments.

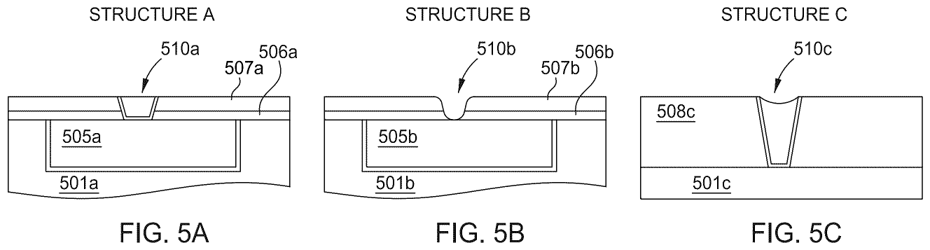

FIGS. 5B, 6B, 7B, 8B, 9B, 10B, 11B, 12B, 13B, 14B, 15B, 16B, and 17B depict schematic, cross-sectional views of the formation of a resistive memory cell, according to one or more embodiments.

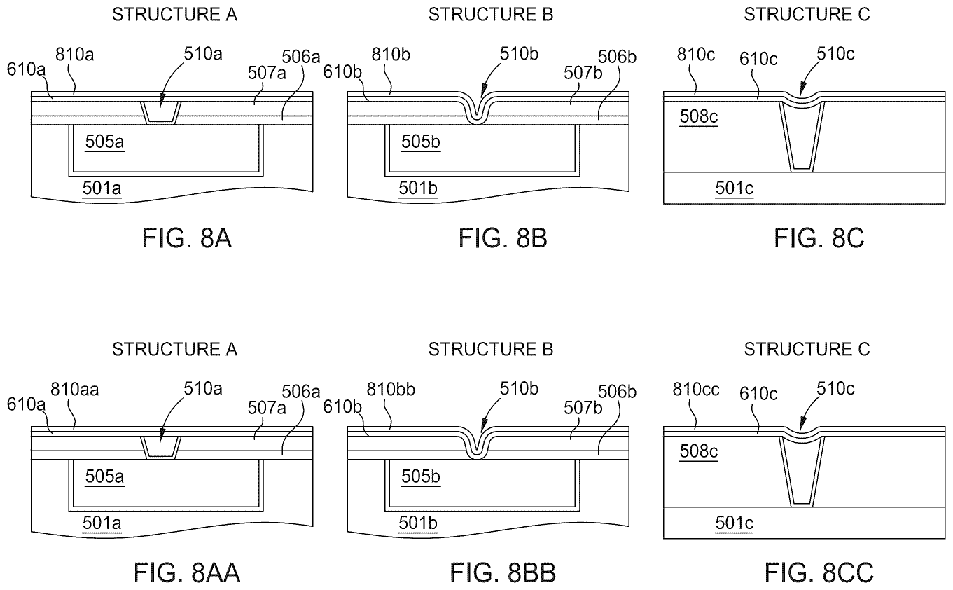

FIG. 8BB, 9BB, and 10BB depict schematic, cross-sectional views of the formation of a resistive memory cell, according to one or more embodiments.

FIGS. 5C, 6C, 7C, 8C, 9C, 10C, 11C, 12C, 13C, 14C, 15C, 16C, and 17C depict schematic, cross-sectional views of the formation of a resistive memory cell, according to one or more embodiments.

FIG. 8CC, 9CC, and 10CC depict schematic, cross-sectional views of the formation of a resistive memory cell, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Resistive random access memory (ReRam) devices and systems are formed using memory cells that have a resistive switching memory element having two or more stable resistance states. Voltage pulses are used to switch the resistive switching memory element from one resistance state to the other. For example, a bistable memory cell having a resistive switching memory element with two stable resistance states can be placed in a high resistance state or a low resistance state by applying suitable voltages or currents.

ReRam's versatility and advantageous features make it a significant focus of research and development across various sectors aiming to meet the increasing demand for advanced memory solutions. For example, ReRam is explored as a promising alternative to NAND flash memory for data storage in consumer electronics due to its faster write and erase times, lower power consumption, and higher endurance. ReRam's ability to mimic synaptic functions makes it suitable for neuromorphic architectures, that aim to replicate the brain's neural networks for advanced computer tasks like pattern recognition and machine learning. The inherent variability and randomness in ReRam devices can be utilized for hardware security applications, such as Physical Unclonable Functions (PUFs) for device authentication and secure key storage. The compact size and low power consumption of ReRam make it suitable for wearable devices, enabling persistent data storage and efficient processing capabilities. In automobile electronics, ReRam can enhance the reliability and performance of memory systems in automotive applications, which require robust and durable nonvolatile memory solutions.

With such a wide range of applications, challenges and opportunities in terms of cycling capabilities (i.e., endurance of the memory cell) and temperature retention (i.e., variability and security of memory design) need to be addressed. Resistive switching memory cells generally have either high cycling capability with poor high temperature retention or high temperature retention with poor cycling capabilities.

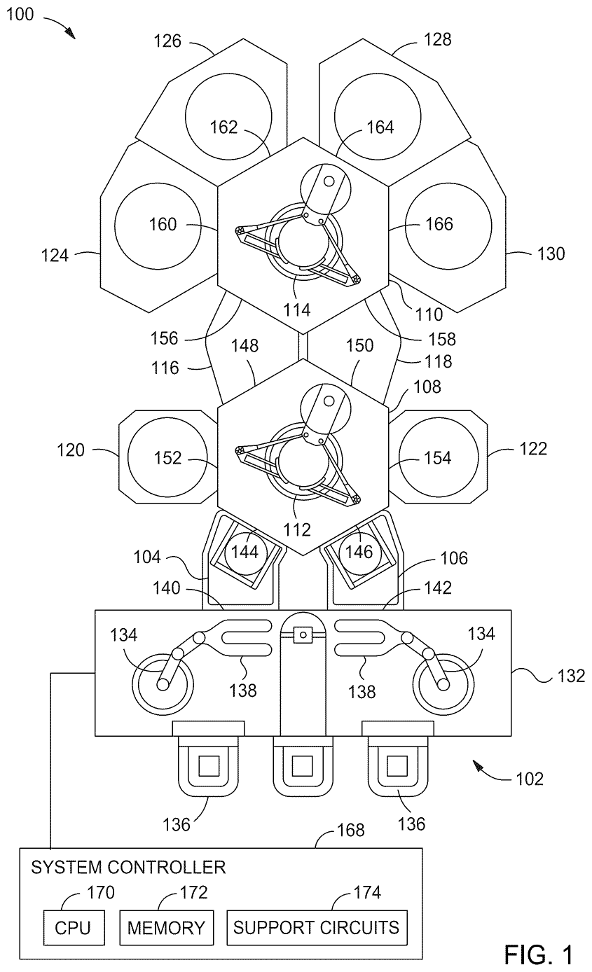

Beneficially, embodiments provided herein provide systems and methods for fabricating resistive memory devices such as ReRam devices with both high cycling and high temperature retention. More specifically, systems and methods provided herein include the fabrication of complex ReRam devices using a single Physical Vapor Deposition process in a single chamber without breaking vacuum. Additionally, embodiments provided herein further include systems and methods for etching complex ReRam devices with improved lateral etch control, no sidewall shorting, and high throughput. FIG. 1 is a schematic top view of a processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, and 130. As detailed herein, in some embodiments, substrates in the processing system 100 are processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, in some embodiments, the processing system 100 may provide for an integrated solution for some processing of substrates. However, in some embodiments, an ex-situ processing method may be used. The ex-situ processing method includes the performance of a plurality of process steps within a first multi-chamber processing system and a different plurality of process steps being performed within a second multi-chamber processing system. The ex-situ processing method includes a vacuum break step that is needed to transfer the substrates between the first and the second processing systems.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, and 142 coupled to the factory interface 102 and respective ports 144, and 146 coupled to the transfer chamber 108. The transfer chamber 108 further has respective ports 148, and 150 coupled to the holding chambers 116, and 118 and respective ports 152, 154 coupled to processing chambers 120, and 122. Similarly, the transfer chamber 110 has respective ports 156, and 158 coupled to the holding chambers 116, 118 and respective ports 160, 162, and 164, and 166 coupled to processing chambers 124, 126, 128, and 130. The ports 144, 146, 148, 150, 152, 154, 156, 158, 160, 162, 164, and 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, and 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, and 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes, such as Physical Vapor Deposition (PVD). The processing chamber 120 may be a Centris®Sym3® or Selectra™ Etch chamber available from Applied Materials of Santa Clara, Calif. The processing chamber 122 may be a Clarion™ or SiCoNi™ Pre-clean chamber available from Applied Materials of Santa Clara, Calif. The processing chamber 126, 128, or 130 may be a Centura™ Epi chamber or Endura® PVD chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, and 130 of the processing system 100 or by controlling controllers associated with the chambers 104, 106, 108, 110, 116, 118, 120, 122, 124, 126, 128, and 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods disclosed herein.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

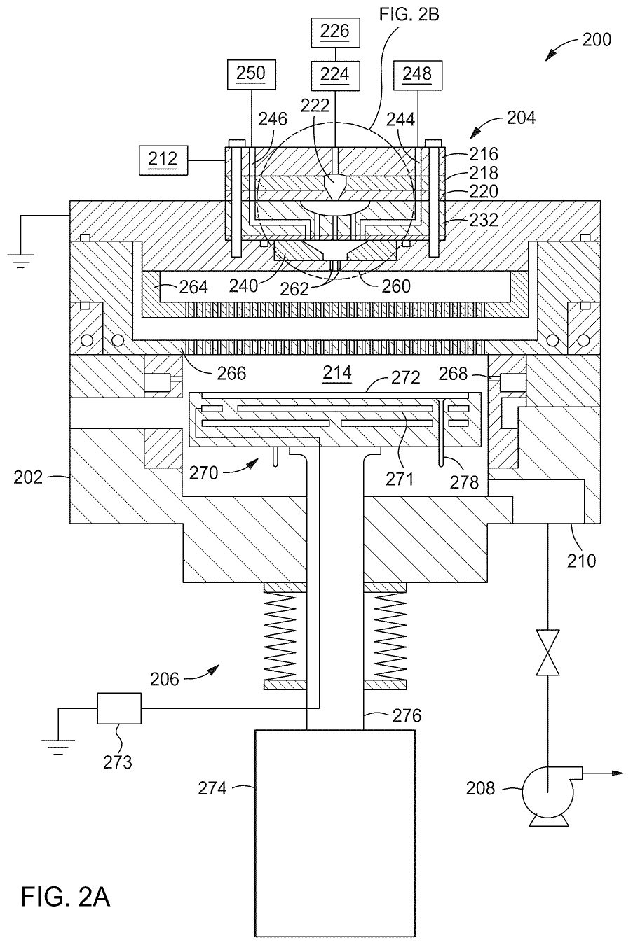

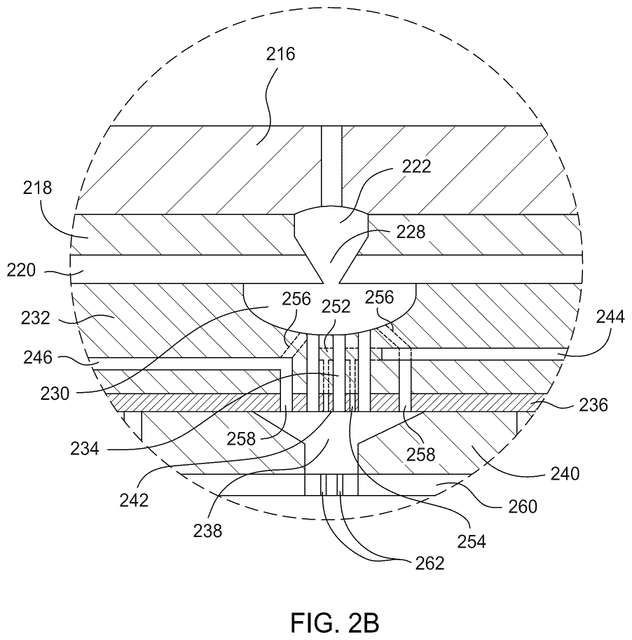

FIG. 2A is a cross sectional view of a processing chamber 200, according to one or more embodiments, that is adapted to perform a pre-clean process and/or a plasma enhanced etching or deposition process. The processing chamber 200 may be the processing chamber 122 shown in FIG. 1. FIG. 2B is an enlarged view of a portion of the processing chamber 200 of FIG. 2A.

The processing chamber 200 may be particularly useful for performing a thermal or plasma-based cleaning process and/or a plasma assisted dry etch process. The processing chamber 200 includes a chamber body 202, a lid assembly 204, and a support assembly 206. The lid assembly 204 is disposed at an upper end of the chamber body 202, and the support assembly 206 is at least partially disposed within the chamber body 202. A vacuum system can be used to remove gases from processing chamber 200. The vacuum system includes a vacuum pump 208 coupled to a vacuum port 210 disposed in the chamber body 202. The processing chamber 200 also includes a controller 212 for controlling processes within the processing chamber 200.

The lid assembly 204 includes stacked components adapted to provide precursor gases and/or a plasma to a processing region 214 within the processing chamber 200. A first plate 216 is coupled to a second plate 218. A third plate 220 is coupled to the second plate 218. The lid assembly 204 may be connected to a power source (not shown) for supplying a plasma to a cone-shaped chamber 222 formed in the lid assembly 204. The lid assembly 204 can also be connected to a remote plasma source 224 that creates the plasma upstream of the lid stack. The remote plasma cavity (e.g., the processing region 214, the first plate 216, and the second plate 218 in FIGS. 2A-2B) is coupled to a gas source 226 via the remote plasma source 224 (or the gas source 226 is coupled directly to the lid assembly 204 in the absence of the remote plasma source 224). The gas source 226 may include a gas source that is adapted to provide helium, argon, or other inert gas. In some configurations, the gas provided by the gas source 226 can be energized into a plasma that is provided to the lid assembly 204 by use of the remote plasma source 224. In alternate embodiments, the gas source 226 may provide process gases that can be activated by the remote plasma source 224 prior to being introduced to a surface of the substrate that is disposed within the processing chamber 200. Referring to FIG. 2B, the cone-shaped chamber 222 has an opening 228 that allows a formed plasma to flow from the remote plasma source 224 to a volume 230 formed in a fourth plate 232 of the lid assembly 204.

In some configurations of the lid assembly 204, a plasma is generated within the cone-shaped chamber 222 by the application of energy delivered from a plasma source. In one example, the energy can be provided by biasing the lid assembly 204 to capacitively couple RF, VHF and/or UHF energy to the gases positioned in the cone-shaped chamber 222. In this configuration of the lid assembly 204, the remote plasma source 224 may not be used, or not be installed within the lid assembly 204.

A central conduit 234, which is formed in the fourth plate 232, is adapted to provide the plasma generated species provided from the volume 230 through a fifth plate 236 to a mixing chamber 238 formed in a sixth plate 240 of the lid assembly 204. The central conduit 234 communicates with the mixing chamber 238 through an opening 242 in the fifth plate 236. The opening 242 may have a diameter less than, greater than or the same as a diameter of the central conduit 234. In the embodiment of FIG. 2B, the opening 242 has diameter the same as the central conduit 234.

The fourth plate 232 also includes inlets 244 and 246 that are adapted to provide gases to the mixing chamber 238. The inlet 244 is coupled to a first gas source 248 and the inlet 246 is coupled to a second gas source 250. The first gas source 248 and the second gas source 250 may include processing gases as well as inert gases, for example inert gases such as argon and/or helium, utilized as a carrier gas. The first gas source 248 may include ammonia (NH3) as well as argon (Ar). The second gas source 250 may contain fluorine containing gases, hydrogen containing gases, or a combination thereof. In one example, the second gas source 250 may contain hydrogen fluoride (HF) as well as argon (Ar).

As illustrated in FIG. 2B, in some configurations, the inlet 244 is coupled to the mixing chamber 238 through a cylindrical channel 252 (shown in phantom) and holes 254 formed in the fifth plate 236. The inlet 246 is coupled to the mixing chamber 238 through a cylindrical channel 256 (shown in phantom) and holes 258 formed in the fifth plate 236. The holes 254, 258 formed in the fifth plate 236 are generally sized so that they enable a uniform flow of gases, which are provided from their respective gas source 248, 250, into the mixing chamber 238. In one configuration, the holes 258 have a diameter that is less than a width of the opening defined by the opposing sidewalls of the cylindrical channel 256 formed in the fourth plate 232. The holes 258 are typically distributed around the circumference of the center-line of the cylindrical channel 256 to provide uniform fluid flow into the mixing chamber 238. In one configuration, the holes 254 have a diameter that is less than a width of the opening defined by the opposing sidewalls of the cylindrical channel 252 formed the fourth plate 232. The holes 254 are typically distributed around the circumference of the center-line of the cylindrical channel 252 to provide uniform fluid flow into the mixing chamber 238.

The inlets 244 and 246 provide respective fluid flow paths laterally through the fourth plate 232, turning toward and penetrating through the fifth plate 236 to the mixing chamber 238. The lid assembly 204 also includes a seventh plate or first gas distributor 260, which may be a gas distribution plate, such as a showerhead, where the various gases mixed in the lid assembly 204 are flowed through perforations 262 formed therein. The perforations 262 are in fluid communication with the mixing chamber 238 to provide flow pathways from the mixing chamber 238 through the first gas distributor 260. Referring back to FIG. 2A, a blocker plate 264 and a gas distribution plate, such as a second gas distribution plate 266, which may be a showerhead, is disposed below the lid assembly 204.

Alternatively, a different cleaning process may be utilized to clean the substrate surface. For example, a remote plasma containing helium (He) and ammonia (NH3) may be introduced into the processing chamber 200 through the lid assembly 204, while ammonia (NH3) may be directly injected into the processing chamber 200 via a separate gas inlet 268 that is disposed at a side of the chamber body 202 and coupled to a gas source (not shown).

The support assembly 206 may include a substrate support 270 to support a substrate 272 thereon during processing. The substrate support 270 may be coupled to an actuator 274 by a shaft 276 which extends through a centrally-located opening formed in a bottom of the chamber body 202. The actuator 274 may be flexibly sealed to the chamber body 202 by a bellows that prevents vacuum leakage around the shaft 276. The actuator 274 allows the substrate support 270 to be moved vertically within the chamber body 202 between a processing position and a loading position. The loading position is slightly below the opening of a tunnel formed in a sidewall of the chamber body 202.

The substrate support 270 has a flat, or a substantially flat, substrate supporting surface for supporting a substrate 272 to be processed thereon. The substrate support 270 may be moved vertically within the chamber body 202 by the actuator 274, which is coupled to the substrate support 270 by the shaft 276. For some process operations, the substrate support 270 may be elevated to a position in close proximity to the lid assembly 204 to control the temperature of the substrate 272 being processed. As such, the substrate 272 may be heated via radiation emitted from the second gas distribution plate 266, or another radiant source, or by convection or conduction from the second gas distribution plate 266 through an intervening gas. In some process steps, the substrate may be disposed on lift pins 278 to perform additional thermal processing operations, such as performing an annealing step.

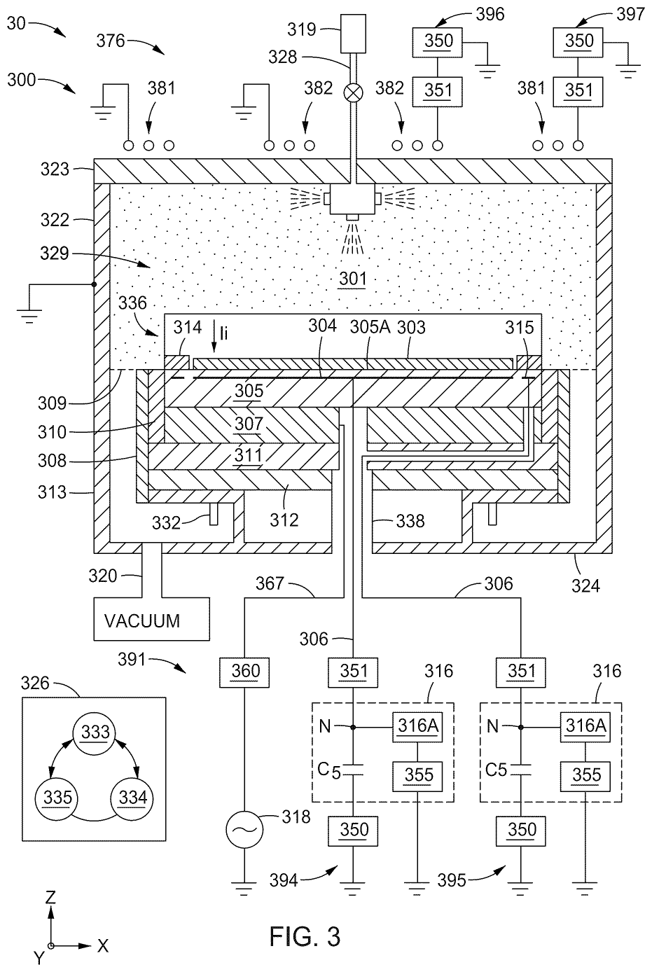

FIG. 3 is a schematic cross-sectional view of a processing system 30 that is configured to perform one or more of the plasma processing methods set forth herein. In some embodiments, the processing systems 30 is configured for plasma-assisted etching processes, such as a reactive ion etch (RIE) plasma processing. However, it should be noted that the embodiments described herein may also be used with processing systems configured for use in other plasma-assisted processes, such as plasma-enhanced deposition processes, for example, plasma-enhanced chemical vapor deposition (PECVD) processes, plasma-enhanced atomic layer deposition (PEALD) processes, plasma treatment processing or plasma-based ion implant processing, for example, plasma doping (PLAD) processing.

The processing system 30 generally includes a processing chamber 300, a lid assembly 376, a support assembly 336, and a system controller 326. As shown, the processing system 30 includes a plurality of plasma source assemblies that are each adapted to deliver a radio frequency (RF), direct current (DC) or pulsed voltage waveforms to one or more electrodes and/or one or more coils disposed within the processing chamber 300. In one configuration example, as shown in FIG. 3, the processing chamber 300 includes four plasma source assemblies, such as a first capacitively coupled plasma (CCP) assembly 394, a second capacitively coupled plasma (CCP) assembly 395, a first inductively coupled plasma (ICP) assembly 396, and a second inductively coupled plasma (ICP) assembly 397. In some embodiments, the processing chamber 300 includes an additional optional source assembly 391 that is configured to deliver an RF signal to an electrode within the processing chamber 300 to generate and/or sustain a plasma 301 within a processing volume 329 of the processing chamber 300.

The processing chamber 300 typically includes a chamber body 313 that includes one or more sidewalls 322 and a chamber base 324, which collectively, with a chamber lid 323 of the lid assembly 376, define the processing volume 329. The one or more sidewalls 322 and chamber base 324 generally include materials that are sized and shaped to form the structural support for the elements of the processing chamber 300 and are configured to withstand the pressures and added energy applied to them while the plasma 301 is generated within a vacuum environment maintained in the processing volume 329 of the processing chamber 300 during processing. In one example, the one or more sidewalls 322 and chamber base 324 are formed from a metal, such as aluminum, an aluminum alloy, or a stainless steel alloy. A gas inlet 328 disposed through the chamber lid 323 is used to deliver one or more processing gases to the processing volume 329 from a processing gas source 319 that is in fluid communication therewith. The processing chamber 300 includes a vacuum pump 320. A substrate 303 is loaded into, and removed from, the processing volume 329 through an opening (not shown) in one of the one or more sidewalls 322, which is sealed with a slit valve (not shown) during plasma processing of the substrate 303. The gas source 319 is configured to provide one or more of the processing gases to the processing volume 329 of the processing chamber 300. The gas source 319 is configured to provide one or more gases utilized in the methods described herein, such as a halogen containing gas (e.g., Cl2, Br2, F2, I2, HBr, HCl, CH3F, C4F8, CHF3, etc.), a hydrogen containing gas (e.g., H₂), an oxygen containing gas (e.g., O₂), and one or more inert gases (e.g., He, Ar, Ne, Kr, etc.).

The system controller 326, also referred to herein as a processing chamber controller, includes a central processing unit (CPU) 333, a memory 334, and support circuits 335. The system controller 326 can also form part of the system controller 168 described above. The system controller 326 is used to control the process sequence used to process the substrate 303, including the plasma processing and substrate biasing methods described herein. The CPU 333 is a general-purpose computer processor configured for use in an industrial setting for controlling the processing chamber and sub-processors related thereto. The memory 334 described herein, which is generally non-volatile memory, may include random access memory, read-only memory, floppy or hard disk drive, or other suitable forms of digital storage, local or remote. The support circuits 335 are conventionally coupled to the CPU 333 and comprise cache, clock circuits, input/output subsystems, power supplies, and the like, and combinations thereof. Software instructions (program) and data can be coded and stored within the memory 334 for instructing a processor within the CPU 333. A software program (or computer instructions) readable by CPU 333 in the system controller 326 determines which tasks are performable by the components in the processing system 30. Typically, the software program, which is readable by CPU 333 in the system controller 326, includes code, which, when executed by the processor (CPU 333), performs tasks relating to the plasma processing methods described herein. The program may include instructions that are used to control the various hardware and electrical components within the processing system 30 to perform the various process tasks and various process sequences used to implement the methods described herein.

In some embodiments, the lid assembly 376 includes the chamber lid 323 and the one or more plasma source assemblies, such as two inductively coupled plasma (ICP) assemblies 396, 397 illustrated in FIG. 3. As shown in FIG. 3, each ICP assembly 396, 397 includes a coil 381, 382, respectively, that is configured to inductively couple a biasing signal generated by a generator 350 to a plasma 301 formed in the processing volume 329 of the processing chamber 300 during plasma processing. In this configuration, the chamber lid 323 includes a dielectric material that is configured to allow the fields generated by the coils 381, 382 during the delivery of the biasing signal, such as an RF signal provided by the generator 350 and through an RF match 351 to help generate and sustain the plasma 301 in the processing volume 329. The provided RF signal can include the delivery of an RF waveform at a frequency between 100 kHz and 120 MHz, such as frequency between 2 MHz and 60 MHz, at a RF power level between 100 Watts and about 1000 Watts.

However, in some alternate embodiments of the processing chamber 300, the lid assembly 376 includes the chamber lid 323 that includes one or more of the capacitively coupled plasma (CCP) assemblies, such as an RF driven showerhead assembly that is disposed over a surface of a substrate during plasma processing.

The substrate support assembly 336, as shown in FIG. 3, includes a substrate support 305 (e.g., ESC substrate support) and one or more lower electrodes, which are coupled to a biasing source assembly, such as the source assemblies 394, 395. In some embodiments, the substrate support assembly 336 can additionally include a support base 307, an insulator plate 311, a ground plate 312 and substrate lift assembly 332. The support base 307 is electrically isolated from the chamber base 324 by the insulator plate 311, and the ground plate 312 is interposed between the insulator plate 311 and the chamber base 324. The substrate support 305 is thermally coupled to and disposed on the support base 307. In some embodiments, the support base 307 is configured to regulate the temperature of the substrate support 305, and the substrate 303 disposed on the substrate support 305, during substrate processing. Typically, the substrate support 305 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 305 further includes the bias electrode 304 embedded in the dielectric material thereof.

The one or more lower electrodes can include a bias electrode 304 and/or an edge electrode 315 that are formed within the substrate support 305, and are coupled to one or more source assemblies, such as the two source assemblies 394, 395. The source assembly 394 is coupled to the bias electrode 304 and the source assembly 395 is coupled to the edge electrode 315, and are each configured to deliver a waveform generated by a source generator 350 to a plasma 301 formed in the processing volume 329 of the processing chamber 300 during plasma processing. In some embodiments, the source assemblies 394, 395 include an RF power source, a DC power source, or a pulsed DC power source that are configured to deliver a biasing signal, such as an RF signal, constant DC signal, or asymmetric pulsed voltage waveform provided by the generator 350 to help bias the substrate and/or generate and sustain the plasma 301 in the processing volume 329. In some embodiments, the biasing signal comprises an RF signal that is provided at a frequency between 100 kHz and 120 MHz, such as frequency between 2 MHz and 60 MHz, at an RF power level between zero and about 1000 Watts, such as between about 5 Watts and 500 Watts. In some other embodiments, the biasing signal comprises an asymmetric pulsed DC signal that is provided at a frequency between 100 kHz and 500 kHz, an on-time duty cycle of between 10% and 95%, at an applied voltage level between about +100 Volts and −8000 volts, such as between about +10 Volts and −5000 volts. In some other embodiments, the biasing signal comprises a constant DC signal that is provided at an applied voltage level between about +5000 Volts and −8000 volts.

In one configuration, the bias electrode 304 is a chucking pole used to secure (i.e., chuck) the substrate 303 to the substrate supporting surface 305A of the substrate support 305 and to bias the substrate 303 with respect to the processing plasma 301 using one or more of the biasing schemes described herein. Typically, the bias electrode 304 is formed of one or more electrically conductive parts, such as one or more metal meshes, foils, plates, or combinations thereof.

The source assemblies 394, 395 may also each include a clamping network 316 so that a high voltage bias applied to the bias electrode 304 and/or edge control electrode 315. In some embodiments, the bias electrode 304 is electrically coupled to a clamping network 316 and the edge electrode 315 is electrically coupled to a clamping network 316. The clamping networks provide a chucking voltage thereto, such as static DC voltage between about −5000 V and about +5000 V, using an electrical conductor, such as the coaxial power delivery line 306 (e.g., a coaxial cable). The clamping network 316 includes bias compensation circuit elements 316A, a DC power supply 355, and a bias compensation module blocking capacitor, which is also referred to herein as the blocking capacitor C5. The blocking capacitor C5 is disposed between the output of a generator 350 and the bias electrode 304. Applying similarly configured bias waveforms and clamping voltages to the bias electrode 304 and edge control electrode 315 can help improve the plasma uniformity across the surface of the substrate during processing and thus improve the plasma processing process results.

As discussed above, in some embodiments, the substrate support assembly 336 includes the edge control electrode 315 that is positioned below the edge ring 314 and surrounds the bias electrode 304 and/or is disposed a distance from a center of the bias electrode 304. In general, for a processing chamber 300 that is configured to process circular substrates, the edge control electrode 315 is annular in shape, is made from a conductive material, and is configured to surround at least a portion of the bias electrode 304. In some embodiments, such as shown in FIG. 3, the edge control electrode 315 is positioned within a region of the substrate support 305. In some embodiments, as illustrated in FIG. 3, the edge control electrode 315 includes a conductive mesh, foil, and/or plate that is disposed a similar distance (i.e., Z-direction) from the substrate supporting surface 305A of the substrate support 305 as the bias electrode 304. In some other embodiments, the edge control electrode 315 includes a conductive mesh, foil, and/or plate that is positioned on or within a region of a quartz pipe 310, which surrounds at least a portion of the bias electrode 304 and/or the substrate support 305. Alternatively, in some other embodiments (not shown), the edge control electrode 315 is positioned within or is coupled to the edge ring 314, which is disposed on and adjacent to the substrate support 305. In this configuration, the edge ring 314 is formed from a semiconductor or dielectric material (e.g., AlN, etc.).

In some embodiments, the processing chamber 300 includes a source assembly 391 that is configured to deliver an RF signal to an electrode, such as the support base 307, within the processing chamber 300 via a conductive line 367 to generate and/or sustain, such as the support base 307 the plasma 301 in the processing volume 329. In some embodiments, the source assembly 391 includes an RF generator 318 that is configured to deliver an RF waveform signal having a frequency that is greater than 1 MHz or more, or about 2 MHz or more, such as about 13.56 MHz or more through an RF match 360 that is connected to the electrode, which is used to RF bias a substrate during processing.

### ReRam Stack Formation Process Sequence

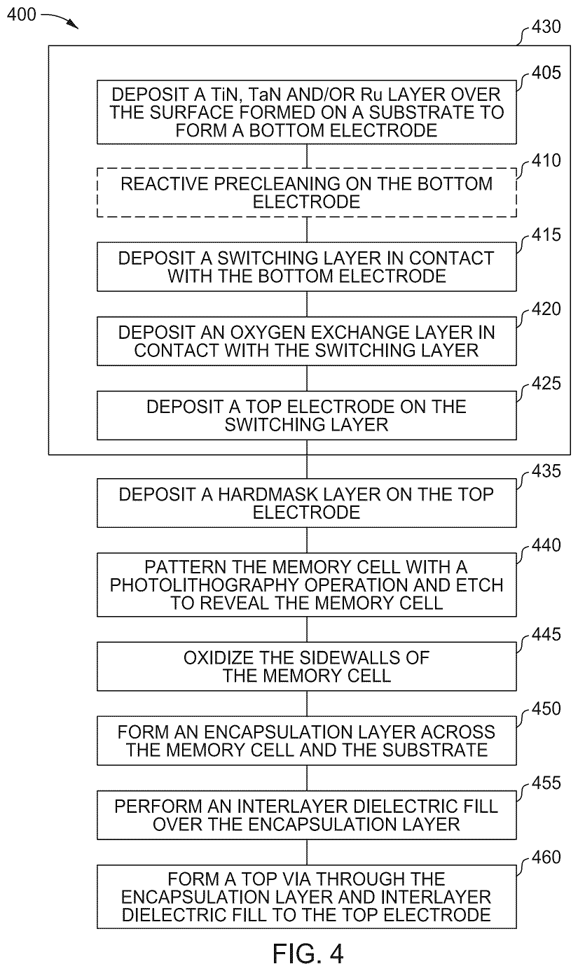

FIG. 4 includes a method 430 for forming highly reliable ReRam memory cell (or stacks). FIGS. 5A-10A, 5B-10B, and 5C-10C, corresponding to structures A, B, and C, respectively, illustrate examples of a ReRam Stack formation process sequence according to one or more embodiments of the disclosure provided herein.
FIGS. 5A, 5B, and 5C depict three different base structures A, B, C, on which the ReRam Stacks are formed. Referring to FIG. 5A, the base structure A includes a substrate 501a having a metal feature 505a formed therein. In one or more embodiments, the metal feature 505a may be formed of a metallic material such as copper (Cu), tungsten (W), chromium (Cr), molybdenum (Mo), aluminum (Al), gold (Au), nickel (Ni), palladium (Pd), or the like, or a combination thereof. In one or more embodiments, the substrate 501a may be formed of any suitable substrate material. For example, the substrate 501a can include a substrate formed from a III-V compound semiconductor material, silicon, crystalline silicon (e.g., Si<100> or Si<111>), silicon oxide, silicon germanium, doped or undoped silicon, doped or undoped polysilicon, silicon nitride, quartz, glass (e.g., borosilicate glass), sapphire, alumina, and/or ceramic materials. In at least one embodiment, the substrate 501a can include a monocrystalline p-type or n-type silicon substrate. In some embodiments, the substrate 501a can include a polycrystalline p-type or n-type silicon substrate. In another embodiment, the substrate 501a can include a p-type or an n-type silicon solar substrate.

As shown in FIG. 5A, a first layer 506a is formed over the substrate 501a and metal feature 505a, and a second layer 507a is formed over the first layer 506a. In one or more embodiments, the first layer 506a may be a conductive layer. In some examples, the first layer 506a may be formed of a metallic material, such as copper (Cu), tungsten (W), chromium (Cr), molybdenum (Mo), aluminum (Al), gold (Au), nickel (Ni), palladium (Pd), or the like, or a combination thereof. In at least one embodiment, the first layer 506a may include a layer of tungsten on copper. In one or more embodiments, the second layer 507a may be an insulating layer. In some examples the second layer 507a may be formed from a flowable build-up material, typically in the form of a dry film. Accordingly, although herein referred to as a “second layer 507a,” the second layer 507a can also be described as a dielectric layer. In some embodiments, the second layer 507a can be formed of an epoxy resin material having a ceramic filler, such as silica (SiO₂) particles. Other examples of ceramic fillers that can be utilized to form the second layer 507a include aluminum nitride (AlN), aluminum oxide (Al₂O₃), silicon carbide (SiC), silicon nitride (Si₃N₄, Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. As shown, a via 510a filled with a conductive material is formed through the first layer 506a and second layer 507a, such that the conductive material is in contact with the metal feature 505a. In one example, the conductive fill material in the via 510a may include tantalum nitride lined copper layer.

As shown in FIG. 5B, a first layer 506b is formed over a substrate 501b and metal feature 505b, and a second layer 507b is formed over the first layer 506b. The metal feature 505b may be formed of the same material composition as the metal feature 505a described above. In one or more embodiments, the first layer 506b may be a conductive layer. The first layer 506b may be formed of the same material composition as the first layer 506a described above. In one or more embodiments, the second layer 507b may be an insulating layer or a dielectric layer. The second layer 507b may be formed of the same material composition as the second layer 507a described above. As shown, a via 510b is formed through the first layer 506b and second layer 507b.

As shown in FIG. 5C, a via 510c filled with a conductive material is formed through a dielectric layer 508c, such that the conductive material is in contact with a metal layer 501c. In one example, the metal layer 501c may be formed of a metallic material such as copper (Cu). In other examples, the metal layer 501c may be formed from tungsten (W), chromium (Cr), molybdenum (Mo), aluminum (Al), gold (Au), nickel (Ni), palladium (Pd), or other suitable metal material. In one example, the conductive fill material in the via 510c may include tantalum nitride lined copper. In yet another embodiment that can be combined with one or more embodiments, the dielectric layer 508c may be a combination of SiCN/SiN/TEOS stack that has a copper blocking layer and a glue layer dielectric which helps with subsequent inter layer dielectric deposition.

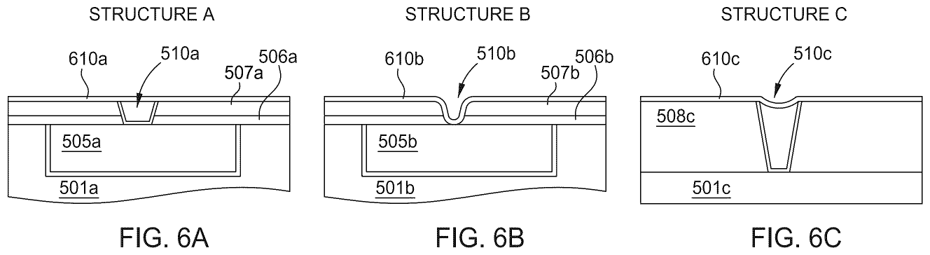

At block 405 of the method 430, the ReRam stack formation process sequence begins with the deposition of a bottom electrode layer 610a, 610b, 610c over the base structures A, B, C, shown in FIGS. 6A, 6B, and 6C, respectively. In one or more embodiments, the bottom electrode layer 610a, 610b, 610c may include titanium nitride (TiN), tantalum nitride (TaN), ruthenium (Ru), or a combination thereof. The deposition process of block 405 may be performed in a processing chamber, such as the processing chamber 126, 128, or 130 shown in FIG. 1, without breaking the vacuum environment of a multi-chamber processing system, such as the processing system 100. In one or more embodiments, the deposition of the bottom electrode layer 610a, 610b, and 610c may be a PVD process.

In some embodiments, a deposition gas used in the deposition process to form the bottom electrode layer 610a, 610b, 610c includes a metal source, such as titanium (Ti)-, tantalum (Ta)-, or ruthenium (Ru)-containing halide precursors or a Ru containing organometallic. The deposition process may be performed at a temperature of between about 20° C. and about 450° C. and at a pressure of between 0.3 Torr and 12 mTorr. During the deposition process, argon (Ar) gas may be supplied at a flow rate of between about 10 sccm and about 20 sccm and Nitrogen (N2) gas may be supplied at a flow rate of between about 10 sccm and about 30 sccm, for example. A cycle of the deposition process at block 405 may be repeated as needed to obtain a desired thickness of the bottom electrode layer, for example, between about 5 times and 100 times.

In one or more embodiments, after the deposition of the bottom electrode layer 610a, 610b, 610c, the ReRam stack shown in FIGS. 6A, 6B, and 6C may be planarized by use of a chemical mechanical planarization (CMP) process.

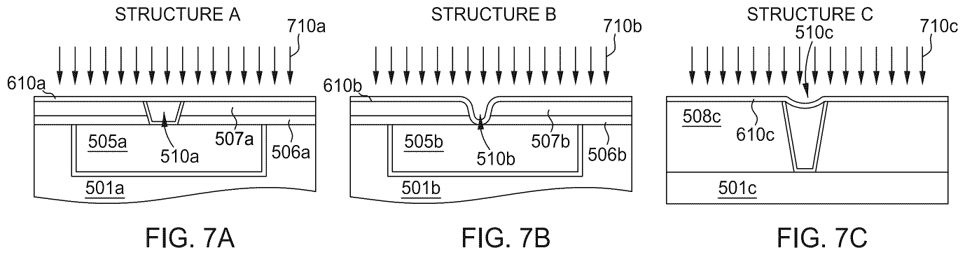

At block 410 of the method 430, the ReRam stack formation process sequence continues with a reactive in-situ preclean process 710a, 710b, 710c on the surface of the bottom electrode layer 610a, 610b, 610c, as shown in FIGS. 7A, 7B, and 7C, respectively. The reactive in-situ pre clean process 710a, 710b, and 710c depicted in FIGS. 7A, 7B, and 7C corresponding to structures A, B, and C, is configured to remove contaminants, such as carbon-containing contaminants (e.g., patterning residues), or oxide-containing contaminants (e.g., native oxide layers) formed on the exposed surface of the bottom electrode layer 610a, 610b, 610c. Minimizing defects and enhancing the uniformity of the surface of the bottom electrode layer (e.g., the surface of the TiN bottom electrode layer 610a, 610b, and 610c after a CMP process) improves both retention and endurance of the ReRam stack.

The reactive in-situ preclean process 710a, 710b, 710c may include an anisotropic remote plasma assisted dry etch process, such as a reactive ion etching (RIE) process, using a plasma formed from a gas including hydrogen (H₂), argon (Ar), helium (He), or a combination thereof. The preclean process may be performed at a temperature of between about 200° C. and about 450° C. and at a pressure of between 25 mTorr and 100 mTorr. During the preclean process, argon (Ar) gas may be supplied at a flow rate of between about 250 sccm and about 550 sccm and Hydrogen (H₂) gas may be supplied at a flow rate of between about 250 sccm and about 550 sccm, for example.

The preclean process 710a, 710b, 710c can be performed in a processing chamber, such as the processing chamber 122 shown in FIG. 1, or the processing chambers 200 or 300 shown in FIGS. 2A-2B and 3. The pre-clean process in block 410 may be performed without breaking vacuum in a multi-chamber processing system, such as the processing system 100 shown in FIG. 1.

At block 415 of the method 430, the ReRam stack formation process sequence continues with the deposition of a tantalum oxide (TaOx) switching layer 810a, 810b, 810c as shown in FIGS. 8A, 8B, and 8C corresponding to structures A, B, and C, respectively.

The TaOx switching layer 810a, 810b, and 810c is deposited over the surface of the bottom electrode layer 610a, 610b, and 610c. Stated otherwise, the TaOx switching layer 810a, 810b, and 810c is in contact with the bottom electrode layer 610a, 610b, and 610c. The deposition process of block 415 may be performed in a processing chamber, such as the processing chamber 126, 128, or 130 shown in FIG. 1, without breaking the vacuum environment of a multi-chamber processing system, such as the processing system 100. In one or more embodiments, the deposition of the TaOx switching layer 810a, 810b, and 810c may be a PVD process. In another embodiment, which may be combined with the previous embodiment, the deposition of the TaOx switching layer 810a, 810b, and 810c is performed in the same PVD chamber used in blocks 405.

In some embodiments, a deposition gas used in the deposition process to form the TaOx switching layer 810a, 810b, 810c includes a metal source such as a tantalum (Ta)-containing organometallic. The deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm. In one or more embodiments, during the deposition process, oxygen (O₂) gas may be supplied at a flow rate of between about 0 sccm and about 100 sccm and/or at a flow rate of between about 25 sccm and about 100 sccm, for example, thus creating a metal rich connection to the bottom electrode layer 610a, 610b, 610c. A cycle of the deposition process at block 415 may be repeated as needed to obtain a desired thickness of the TaOx switching layer 810a, 810b, and 810c, for example, between about 5 times and 100 times.

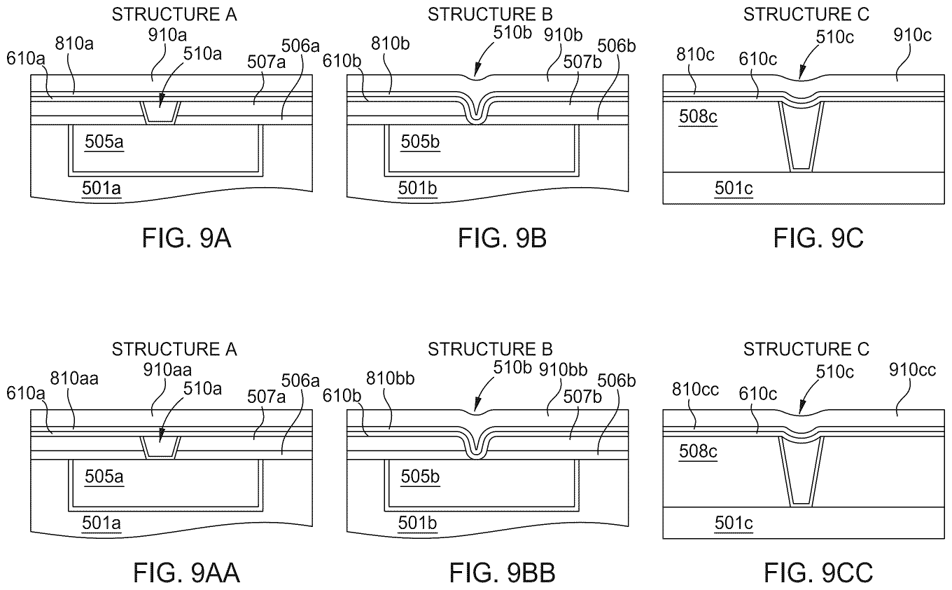

At block 420 of the method 430, the ReRam stack formation process sequence continues with the deposition of a tantalum oxide (TaOx) based oxygen exchange layer 910a, 910b, 910c as shown in FIGS. 9A, 9B, and 9C, corresponding to structures A, B, and C, respectively. The tantalum oxide (TaOx) based oxygen exchange layer 910a, 910b, and 910c is in contact with the TaOx switching layer 810a, 810b, and 810c.

As described above for operation 415, the deposition process of block 420 may be performed in a processing chamber, such as the processing chamber 126, 128, or 130 shown in FIG. 1, without breaking the vacuum environment and within the same single recipe as described above in operation 415 in a multi-chamber processing system, such as the processing system 100. In one or more embodiments, the deposition of the tantalum oxide (TaOx) based oxygen exchange layer 910a, 910b, 910c may be a PVD process. In another embodiment, which may be combined with the previous embodiment, the deposition of the tantalum oxide (TaOx) based oxygen exchange layer 910a, 910b, 910c of block 415 is performed in the same PVD chamber used in previous operations (i.e., in blocks 405 and 415).

In one or more embodiments, a graded tantalum oxide (TaOx) based oxygen exchange layer (e.g., TaOx based oxygen exchange layer 910a, 910b, 910c is formed by co-deposition of tantalum (Ta) from a Ta target using a pulse or DC power source and tantalum oxide (TaOx) from a Ta₂O₅ target using RF or pulsed power source. Deposition may be carried out in a pure argon (Ar) gas. In one embodiment, deposition is carried out in a pure argon (Ar) gas at a flow rate of about 5 sccm to about 15 sccm, under a chamber pressure of about 0.3 mTorr to about 12 mTorr, and at a substrate temperature of about 200° C. to about 400°C. The ratio of Ta to O in the deposited film is controlled by the relative power applied to the two targets, and the layer thickness is determined by the power-on time. Beneficially, this process enables formation of sharp boundaries between the discrete layers of different composition.

In one or more embodiments, during the deposition process at blocks 415 and 420, oxygen (O₂) gas may be supplied at a flow rate of between about 0 sccm and about 100 sccm and/or at a flow rate of between about 25 sccm and about 100 sccm, such that the oxygen content varies with time. The deposition process at block 420 includes adjusting the top interface of the TaOx based oxygen exchange layers 910a, 910b, 910c to a TiN or TaN top electrode cap in preparation for the deposition of the top electrode during block 425. The deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm and nitrogen (N2) gas may be supplied at a flow rate of between about 10 sccm and about 25 sccm. A cycle of deposition process may be repeated as needed to obtain a desired thickness of the TaOx based oxygen exchange layers 910a, 910b, 910c, for example, between about 5 times and 100 times.

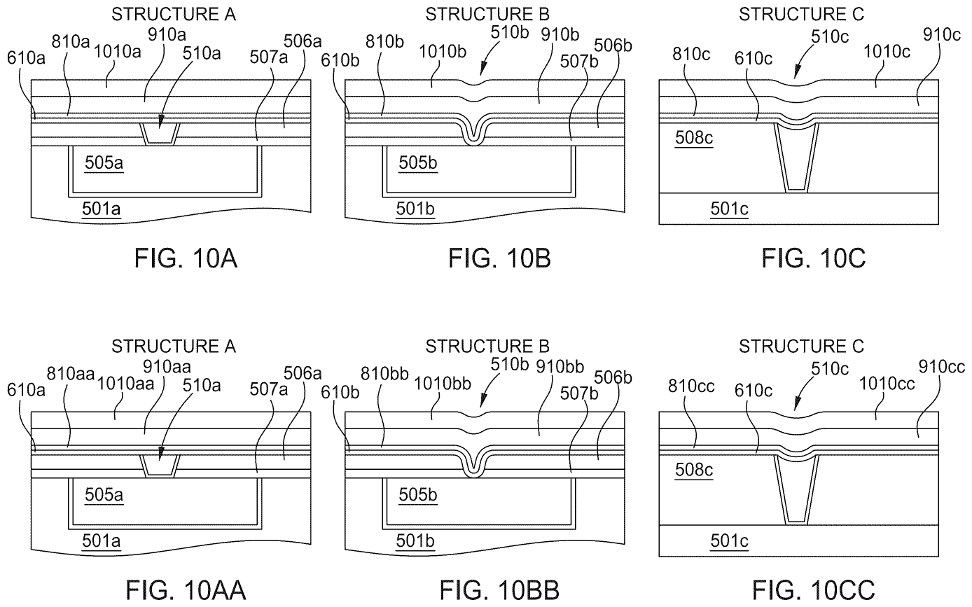

At block 425 of the method 430, the ReRam stack formation process sequence culminates with the deposition of a titanium nitride (TiN) or tantalum nitride (TaN) top electrode 1010a, 1010b, and 1010c as shown in FIGS. 10A, 10B, and 10C corresponding to structures A, B, and C respectively. The titanium nitride (TiN) or tantalum nitride (TaN) top electrode 1010a, 1010b, and 1010c is in contact with the adjusted TaOx based oxygen exchange layer 910a, 910b, and 910c.

As described above for operations 415 and 420, the deposition process of block 425 may be performed in a processing chamber, such as the processing chamber 126, 128, or 130 shown in FIG. 1, without breaking vacuum environment in a multi-chamber processing system, such as the processing system 100. In one or more embodiments, the deposition of the titanium nitride (TiN) or tantalum nitride (TaN) top electrode 1010a, 1010b, and 1010c may be a PVD process. In another embodiment, which may be combined with the previous embodiment, the deposition of the titanium nitride (TiN) or tantalum nitride (TaN) top electrode 1010a, 1010b, and 1010c of block 425 is performed in the same PVD chamber used in previous operations (i.e., in blocks 405, 415, and 420).

In one or more embodiments, the deposition process at block 425 may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm and nitrogen (N2) gas may be supplied at a flow rate of between about 10 sccm and about 25 sccm. A cycle of the deposition process may be repeated as needed to obtain a desired thickness of the top electrode 1010a, 1010b, and 1010c, for example, between about 5 times and 100 times.

As described above, the embodiments described herein of the method 430 depicted in FIGS. 5A-10A, 5B-10B, and 5C-10C corresponding to structure A, B, and C, respectively, beneficially provide a highly reliable memory cell for high cycling and high temperature retention. The tantalum oxide (TaOx) based ReRam cell described herein targets high temperature retention and higher cycling. In one or more embodiments, the tantalum oxide (TaOx) based ReRam cell described herein can be achieved without breaking vacuum environment and within the same single recipe as described above using a single PVD chamber with high process consistency and reliability as well as high throughput. Beneficially, the combination of processes described above of method 430 avoids unwanted interface layers and improves process control for the film stack with high throughput. Moreover, the versatility and consistency provides for the implementation of method 430 with thinner films for multiple technology nodes.

### ReRam Stack Formation Alternate Process Sequence

An alternate version of the method 430 depicted in FIG. 4 is illustrated in FIG. 8AA-10AA, 8BB-10BB, and 8CC-10CC, corresponding to structures A, B, and C respectively is provided herein.

The ReRam stack formation alternate process sequence also begins with blocks 405 and 410 as described above corresponding to FIGS. 5A-7A, 5B-7B, and 5C-7C corresponding to structure A, B, and C, respectively as described above. The deposition of the titanium nitride (TiN), tantalum nitride (TaN), and/or ruthenium (Ru) bottom electrode layer 610a, 610b, 610c over the surface formed on a substrate and the reactive in-situ precleaning 710a, 710b, 710c on the bottom electrode layer 610a, 610b, 610c during blocks 405 and 410 are identical in processes and chemistries as described above during the ReRam stack formation process sequence and therefore will not be described again.

At block 415 of the method 430, the ReRam stack formation alternate process sequence continues with the in-situ deposition and oxidation of hafnium (Hf) over the surface of the bottom electrode layer 610a, 610b, and 610c to form a hafnium oxide (HfOx) switching layer 810aa, 810bb, and 810cc. The hafnium oxide (HfOx) switching layer 810aa, 810bb, and 810cc is shown in FIG. 8AA, 8BB, and 8CC corresponding to structures A, B, and C respectively. The deposition process of block 415 may be performed in a processing chamber, such as the processing chamber 126, 128, or 130 shown in FIG. 1, without breaking the vacuum environment of a multi-chamber processing system, such as the processing system 100. In one or more embodiments, the deposition and oxidation of the hafnium oxide (HfOx) switching layer 810aa, 810bb, and 810cc may be a PVD process. In another embodiment, which may be combined with the previous embodiment, the deposition and oxidation of the hafnium oxide (HfOx) switching layer 810aa, 810bb, and 810cc of block 415 is performed in the same PVD chamber used in block 405.

In some embodiments, a deposition gas used in the deposition process of block 415 to form the hafnium oxide (HfOx) switching layer 810aa, 810bb, and 810cc includes a metal source such as a hafnium (Hf)-containing organometallic. The deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm. In one or more embodiments, during the deposition process, Ozone (O3) gas may be supplied at a flow rate of between about 0 sccm and about 100 sccm and/or at a flow rate of between about 25 sccm and about 100 sccm, for example, thus creating a metal rich connection to the bottom electrode layer 610a, 610b, and 610c. A cycle of deposition process may be repeated as needed to obtain a desired thickness of the hafnium oxide (HfOx) switching layer 810aa, 810bb, and 810cc, for example, between about 5 times and 100 times.

At block 420 of the method 430, the ReRam stack formation alternate process sequence continues with the deposition of a tantalum oxide (TaOx) based oxygen exchange layer 910aa, 910bb, and 910cc as shown in FIG. 9AA, 9BB, and 9CC corresponding to structures A, B, and C respectively. The tantalum oxide (TaOx) based oxygen exchange layer 910aa, 910bb, and 910cc is in contact with the HfOx switching layer 810aa, 810bb, and 810cc. As described above for block 415, the deposition process of block 420 may be performed in a processing chamber, such as the processing chamber 126, 128, or 130 shown in FIG. 1, without breaking vacuum environment and within the same single recipe as described above in operation 415 in a multi-chamber processing system, such as the processing system 100. In one or more embodiments, the deposition of the tantalum oxide (TaOx) based oxygen exchange layer 910aa, 910bb, and 910cc may be a PVD process. In another embodiment, which may be combined with the previous embodiment, the deposition of the tantalum oxide (TaOx) based oxygen exchange layer 910aa, 910bb, and 910cc of block 420 is performed in the same PVD chamber used in blocks 405 and 415.

In one or more embodiments, a graded tantalum oxide (TaOx) based oxygen exchange layer (e.g., TaOx based oxygen exchange layer 910a, 910b, 910c is formed by co-deposition of tantalum (Ta) from a Ta target using a pulse or DC power source and tantalum oxide (TaOx) from a Ta₂O₅ target using RF or pulsed power source. Deposition may be carried out in a pure argon (Ar) gas. In one embodiment, deposition is carried out in a pure argon (Ar) gas at a flow rate of about 5 sccm to about 15 sccm, under a chamber pressure of about 0.3 mTorr to about 12 mTorr, and at a substrate temperature of about 200° C. to about 400° C. The ratio of Ta to O in the deposited film is controlled by the relative power applied to the two targets, and the layer thickness is determined by the power-on time. Beneficially, this process enables formation of sharp boundaries between the discrete layers of different composition.

In one or more embodiments, during the deposition process at block 420, oxygen (O₂) gas may be supplied at a flow rate of between about 0 sccm and about 100 sccm and/or at a flow rate of between about 25 sccm and about 100 sccm, such that the oxygen content varies with time, thus adjusting the TaOx based oxygen exchange layer 910aa, 910bb, and 910cc deposited over the HfOx switching layer 810aa, 810bb, 810cc using a single recipe within the same chamber without breaking vacuum.

In other embodiments, the deposition process at block 420 further includes adjusting the TaOx based oxygen exchange layer 910aa, 910bb, and 910cc to include nitrogen (N₂) and oxygen (O₂). The deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm and nitrogen (N₂) gas may be supplied at a flow rate of between about 10 sccm and about 25 sccm. A cycle of deposition process may be repeated as needed to obtain a desired thickness of the tantalum oxide (TaOx) based oxygen exchange layer 910aa, 910bb, and 910cc, for example, between about 5 times and 100 times.

The graded tantalum oxide (TaOx) based oxygen exchange layer 910aa, 910bb, and 910cc with the further inclusion of N₂ and O₂ rich layer at the top surface where it connects to a TaN or TiN top electrode are specific to the embodiments described herein and beneficially provide high temperature retention and high cycling.

In one or more embodiments, the deposition process of block 420 further includes adjusting the top interface of the TaOx based oxygen exchange layers 910aa, 910bb, and 910cc to a TiN or TaN top electrode cap in preparation for the deposition of the top electrode during block 425. The deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm and nitrogen (N₂) gas may be supplied at a flow rate of between about 10 sccm and about 25 sccm. A cycle of deposition process may be repeated as needed to obtain a desired thickness of the tantalum oxide (TaOx) based oxygen exchange layer 910aa, 910bb, and 910cc, for example, between about 5 times and 100 times.

At block 425 of the method 430, the ReRam stack alternate formation process sequence culminates with the deposition of a titanium nitride (TiN) or tantalum nitride (TaN) top electrode 1010aa, 1010bb, and 1010cc as shown in FIG. 10AA, 10BB, and 10CC corresponding to structures A, B, and C, respectively. The titanium nitride (TiN) or tantalum nitride (TaN) top electrode 1010aa, 1010bb, and 1010cc is in contact with the adjusted Ta based oxygen exchange layer 910aa, 910bb, and 910cc that further includes nitrogen and oxygen.

As described above for operations 415 and 420, the deposition process of block 425 may be performed in a processing chamber, such as the processing chamber 126, 128, or 130 shown in FIG. 1, without breaking vacuum environment and within the same single recipe as described above in operation 415 in a multi-chamber processing system, such as the processing system 100. In one or more embodiments, the deposition of the titanium nitride (TiN) or tantalum nitride (TaN) top electrode 1010a, 1010b, and 1010c may be a PVD process. In another embodiment, which may be combined with the previous embodiment, the deposition of the titanium nitride (TiN) or tantalum nitride (TaN) top electrode 1010a, 1010b, and 1010c of block 425 is performed in the same PVD chamber used in previous operations (i.e., in blocks 405, 415, and 420).

In one or more embodiments, the deposition process may be performed at a temperature of between about 20° C. and about 400° C. and at a pressure of between 0.3 Torr and 12 mTorr. During the deposition process, argon (Ar) gas may be supplied at a flow rate of between about 10 sccm and about 20 sccm and nitrogen (N2) gas may be supplied at a flow rate of between about 10 sccm and about 25 sccm. A cycle of deposition process may be repeated as needed to obtain a desired thickness of the titanium nitride (TiN) or tantalum nitride (TaN) top electrode 1010aa, 1010bb, and 1010cc, for example, between about 5 times and 100 times.

The ReRam stack formation alternate process sequence described herein yields a unique resistive memory cell for high reliability at high temperature. This stack is unique because of the low oxygen levels at the hafnium (Hf) to ruthenium (Ru) and/or Hf to titanium nitride (TiN) interface at the bottom of the stack.

As described above, the embodiments described in this alternate version of method 430 depicted in FIG. 4 and illustrated in FIG. 8AA-10AA, 8BB-10BB, and 8CC-10CC, corresponding to structures A, B, and C, respectively, beneficially provide a new resistive memory cell that uses tantalum and hafnium based dielectrics to optimize for cycling and high temperature retention. That is, by mixing hafnium oxide (HfO₂) with tantalum oxide (TaOx) and using ruthenium (Ru) as an additional interface material, a thin layer of hafnium at the electrode surface on one side and a slightly oxidized tantalum (Ta) surface on the other side of the cell is achieved, thus improving cell performance at higher temperatures as oxygen moves during high temperature operations.

### ReRam Stack Etch Process Sequence

FIG. 4 further includes a method 400 for forming highly reliable ReRam memory cell (or stacks). FIGS. 5A-17A, 5B-17B, and 5C-17C illustrate examples of a ReRam Stack etch process sequence according to one or more embodiments of the disclosure provided herein. The method 400 begins with the completion of the formation of the ReRam stack of method 430. Stated otherwise, with the culmination of the formation of the ReRam stack during operation 425 of method 430, method 400 proceeds to block 435 to prepare the ReRam stack for etching and subsequent processing. Although the ReRam stack etch process sequence is described and illustrated in relation to FIGS. 5A-17A, 5B-17B, and 5C-17C, it is appreciated that the method 400 is not limited to the structures disclosed in FIGS. 5A-17A, 5B-17B, and 5C-17C. In one or more embodiments, the etching process of the ReRam stack of method 400 is a single etch recipe performed in chamber 120 shown in FIG. 1. As discussed earlier, the processing chamber 120 may be a Centris®Sym3® chamber available from Applied Materials of Santa Clara, California, which features high conductance and high symmetry for radical-driven processes. In another embodiment, the etching process of the ReRam stack of method 400 provided herein is an integrated etching performed under the same vacuum environment as the deposition process of method 430. Beneficially, the integrated etching described herein improves process efficiency and reduces contamination thereby increasing throughput.

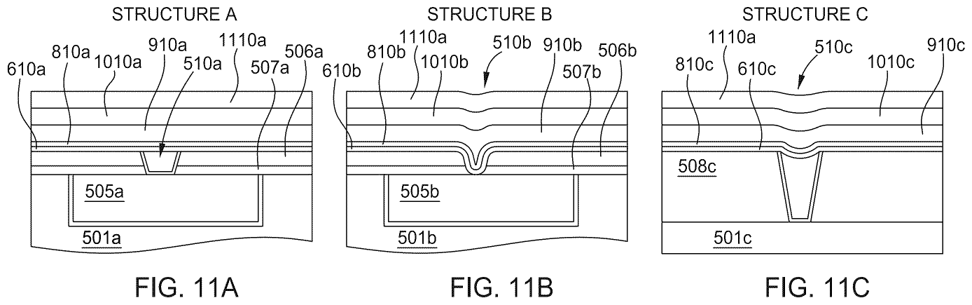

At block 435 of the method 400, as shown in FIGS. 11A, 11B, and 11C corresponding to Structures A, B, and C respectively, the ReRam stack etch process sequence continues with a hardmask layer deposition process. A hardmask 1110a, 1110b, and 1110c is disposed over the titanium nitride (TiN) or tantalum nitride (TaN) top electrode 1010a/1010aa, 1010b/1010bb, and 1010c/1010cc formed during the ReRam stack formation process sequences described above. In one or more embodiments, the hardmask 1110a, 1110b, and 1110c may be disposed using a liquid material pour casting process, a spin-on coating process, a liquid spray coating process, a dry powder coating process, a screen printing process, a doctor blading process, a PVD process, a CVD process, a PECVD process, a flowable CVD (FCVD) process, and ALD process, or an evaporation process. The hardmask 1110a, 1110b, and 1110c can include, but is not limited to chromium (Cr), silver (Ag), Si₃N₄, SiO₂, TiN, SiN, carbon (C) containing materials, or combinations thereof.

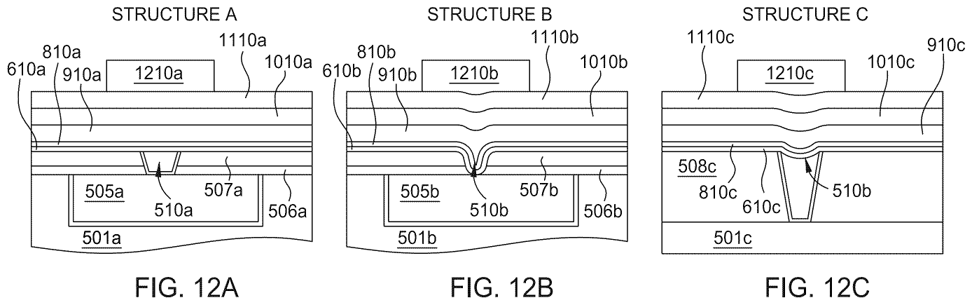

At block 440 of the method 400, a patterned photoresist 1210a, 1210b, and 1210c corresponding to structures A, B, and C, respectively, is disposed over the hardmask 1110a, 1110b, and 1110c as shown in FIGS. 12A, 12B, and 12C. In one example, the patterned photoresist 1210a, 1210b, and 1210c is formed by disposing a photoresist material on the hardmask 1110a, 1110b, and 1110c and performing a lithography process to pattern and develop the photoresist material.

The patterned photoresist 1210a, 1210b, and 1210c allows the selective etching of material by protecting certain regions from unwanted etching in the subsequent process. Still referring to block 440, and as shown in FIGS. 12A, 12B, and 12C corresponding to structures A, B, and C, respectively, a selective etching of the ReRam stack is performed. In one or more embodiments, the etching process includes a plasma etching process that can be performed in one of the processing chambers 200 or 300 illustrated in FIGS. 2A and 3, respectively. The plasma etching process can be a dry chemical etching process that includes the use of a capacitively-coupled-plasma (CCP) or an inductively-coupled-plasma (ICP) source assembly that is configured to provide a radio frequency (RF) signal to a source electrode (e.g., second gas distribution plate 266 in FIG. 2A or coils 381, 382 in FIG. 3) within the processing chamber to generate the plasma within the processing volume of the processing chamber. The RF signal applied to the source electrode can include an RF frequency greater than 100 kilohertz (kHz), equal to or greater than 2 MHz, equal to or greater than 13.56 MHz, equal to or greater than 27 MHz, or equal to or greater than 40 MHz. The RF signal applied to the source electrode can be delivered at a power of about 100 Watts to about 1000 Watts, such as between 150 W and 800 W, or between 150 W and 350 W. In some embodiments, the RF bias power supplied to the source electrode during block 440 can be pulsed at a desired pulsing frequency that can vary between 0.5 kHz and 1,000 kHz and have an on-time duty cycle between 10% and 95%.

In some examples, the etching process performed in block 440 further includes the application of a bias to a substrate disposed on a substrate support to promote bombardment of the surface of the substrate by ions formed in the generated plasma. In some embodiments, etching process of the ReRam stack during block 440 can include the use of a continuous or pulsed RF bias signal that is applied to the substrate by delivery of an RF signal to an electrode (e.g., items 304, or 307) disposed within a substrate support 270, 336 on which the substrate is disposed. The RF signal can include an RF frequency greater than 100 kilohertz (kHz), such as equal to or greater than 2 MHz, equal to or greater than 13.56 MHz, equal to or greater than 27 MHz, or equal to or greater than 40 MHz. The RF bias can be delivered at a power of about 5 Watts to about 500 Watts, such as between 10 W and 200 W, or between 20 W and 100 W. In some embodiments, the RF bias applied during block 504 can be pulsed at a desired pulsing frequency that can vary between 0.5 kHz and 1,000 kHz and have an on-time duty cycle between 10% and 95%.

However, in some examples, the etching process of the ReRam stack during block 440 can include the use of a continuous or pulsed DC bias that is applied to the substrate by delivery of a DC signal to an electrode (e.g., items 304 or 307) disposed within a substrate support 270, 336. The delivered DC signal can be delivered from a pulsed voltage waveform source 273, 394, 395 that includes a pulsed DC voltage power supply. In some embodiments, the pulsed DC bias includes the continuous delivery of pulses, or bursts of pulses, that include an asymmetric voltage waveform pulse that is provided at a frequency between 100 kilohertz (kHz) and 500 kHz. In one example, the pulsed voltage waveform can include applying a voltage between 100 volts and −8,000 volts at an on-time duty cycle between 10% and 95% at a pulsing frequency between 100 kHz and 500 kHz.

In some embodiments, a pulsed source power supplied to the source electrode and a pulsed substrate bias supplied to the substrate biasing electrode during block 504 are synchronized to improve the plasma properties during processing.

The etching process of the ReRam stack during block 440 can include the use of a first process gas mixture that includes a chlorine-containing gas. In one or more embodiments, the first process gas mixture includes diatomic chlorine (Cl₂) gas, nitrogen (N₂), and oxygen (O₂) gas mixture. In one example, the Cl₂ flow rate can be provided from about 20 SCCM to about 450 SCCM, such as from about 20 SCCM and about 300 SCCM. In another example, which may be combined with the previous example, the N₂ flow rate can be provided from about 15 SCCM to about 115 SCCM, such as from about 10 SCCM and about 100 SCCM. In yet another example, which may be combined with the previous examples, the O₂ flow rate can be provided from about 2 SCCM to about 450 SCCM, such as from about 5 SCCM and about 400 SCCM. The first process gas mixture can further include argon (Ar) that is delivered at a flow rate that is from 45 to 550 SCCM. In some examples, the first process gas mixture can include a mixture of gases, such as HBr/O₂, HBr/CHF₃, HBr/CH₃F, H₂/CH₃F/O₂, or HBr/C₄F₈/O₂. The first process gas mixture can further include one or more inert gases, such as argon (Ar) and/or helium (He) at desired flow rates. In one or more embodiments the etching time ranges from about 60 seconds to about 120 seconds.

The etching process of the ReRam stack during block 440 can be performed at a first process pressure of between about 0.001 Torr to about 600 Torr, such as between about 0.05 Torr to about 50 Torr, or between about 0.01 Torr to about 0.5 Torr, or between about 0.01 Torr to about 0.1 Torr. A temperature of the substrate support and substrate can be maintained at a temperature of about −100° C. to about 200° C. during block 440.

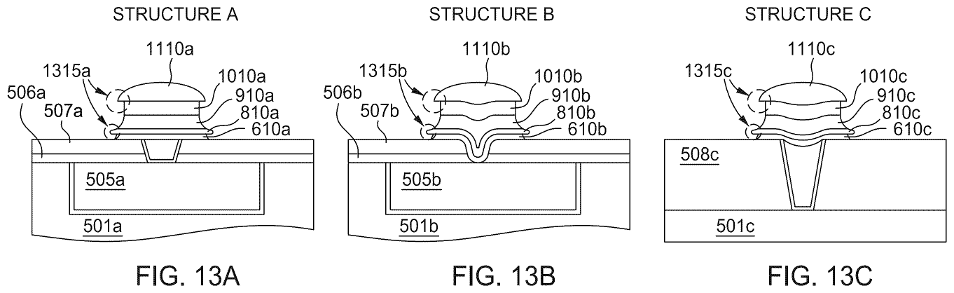

Still referring to block 440 of method 400, as shown in FIGS. 13A, 13B, and 13C corresponding to structures A, B, and C, respectively, overhang features 1315a, 1315b, and 1315c are formed. In one example, the overhang features 1315a, 1350b, and 1350c are purposely formed by etching and undercutting the bottom electrode layer 610a, 610b, and 610c (e.g., the Ru layer and/or the Ru/HfOx stack discussed in the ReRam stack formation alternate process sequence) as desired without any re-sputtering on sidewall. In one or more embodiments, the etching and undercutting of the bottom electrode layer 610a, 610b, and 610c forms overhang features 1315a, 1315b, and 1315c of the switching layer (e.g., of the switching layer 810a/aa, 810b/bb, and 810c/cc) that protrude or extend beyond the surrounding electrode layers. In one example, the overhang features 1315a, 1315b, and 1315c of the HfOx switching layer 810aa, 810bb, and 810cc is formed, by use of a desired etch chemistry, process parameters (e.g., pressure, temperature, etc.), and substrate bias, during the etching process so as to extend or protrude beyond the bottom electrode layer 610a, 610b, and 610c. The etch chemistry and process parameters can be selected to preferentially etch the material bottom electrode layer versus the switching layer. However, in some alternate embodiments, the bottom electrode layer 610a, 610b, and 610c is etched without significant undercut compared to the switching layer 810a/aa, 810b/bb, and 810c/cc.

Still referring to block 440 of method 400, in another example, which may be combined with the previous examples, the overhang features 1315a, 1315b, and 1315c are purposely formed by etching and undercutting the top electrode layer 1010a/1010aa, 1010b/1010bb, and 1010c/1010cc by use of a desired etch chemistry, process parameters (e.g., pressure, temperature, etc.), and substrate bias during the etching process. However, in some alternate embodiments, the top electrode layer 1010a/1010aa, 1010b/1010bb, and 1010c/1010cc is not undercut compared to the hardmask 1110a, 1110b, and 1110c.

Benefits of the single etch recipe discussed herein include the selective formation of overhang features (e.g., overhang features 1315a, 1315b, and 1315c of the HfOx switching layer 810aa, 810bb, and 810cc), that facilitate vertical integration and alignment thus improving the reliability of the ReRam stack. Furthermore, the use of a process gas mixture that includes a chlorine containing gas (e.g., the diatomic chlorine (Cl₂) gas, nitrogen (N₂), and oxygen (O₂) gas mixture) generates a controlled slope (i.e., a tapered profile) from top to bottom of the ReRam stack. The tapered profile promoting the formation of overhang features 1315a, 1315b, and 1315c is achieved because the chlorine species chemically etch the exposed horizontal surfaces of the ReRAM stack, forming gaseous etch by-products that are readily removed from the chamber. At the same time, the addition of nitrogen and oxygen promotes passivation of the sidewalls (e.g., sidewalls 1420a/1430a, 1420b/1430b, and 1420c/1430c) which suppresses lateral etching. The combination of the directional etching from the chlorine species and sidewall passivation from oxygen and nitrogen produces a controlled slope from top to bottom of ReRam stack, thereby providing the desired tapered profile. Additionally, the sidewall passivation provided by nitrogen and oxygen prevents the shorting of the sidewalls of dielectric films located between metal films while providing a high selectivity etch recipe of the ReRam stack. Moreover, processing in a single chamber reduces device exposure to air and particulates, thereby minimizing device defects and increasing throughput.

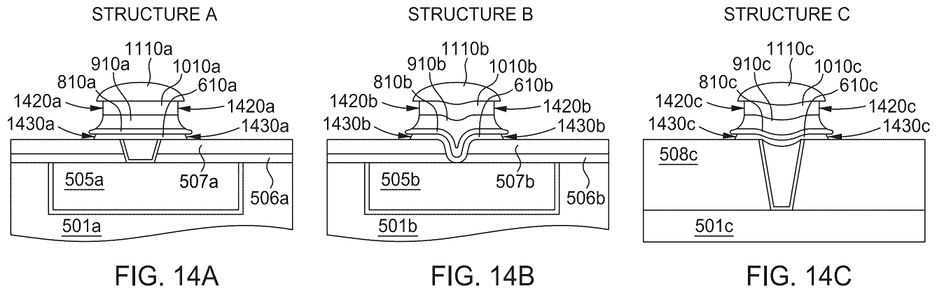

At block 445 as shown in FIGS. 14A, 14B, and 14C sidewalls 1430a/1430b/1430c and 1420a/1420b/1420c are selectively oxidized. In one or more embodiments, the sidewalls 1430a/1430b/1430c and 1420a/1420b/1420c are oxidized on select materials (e.g., sidewalls 1430a/b/c corresponding to the bottom electrode to switching interface (TiN/Hf) and sidewalls 1420a/b/c corresponding to the oxygen exchange layer to top electrode interface (TaOx/TaNx)). In another example, the oxygen exchange layers 910a/aa, 910b/bb, and 910c/cc are oxidized on the sidewalls 1420a, 1420b, and 1420c without chlorine contamination. Avoiding the inclusion of chlorine (e.g., from first process gas mixture during the etching process) from enhances reliability, prevents defects, and reduces the risk of premature dielectric breakdown at the sidewalls, thereby maintaining the integrity of the ReRam stack.

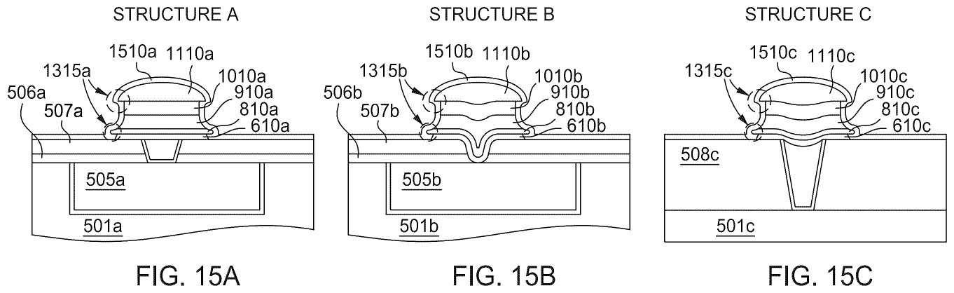

At block 450 as shown in FIGS. 15A, 15B, and 15C corresponding to structures A, B, and C, respectively, an encapsulation layer 1510a, 1510b, and 1510c is disposed over the exposed surfaces of the etched ReRam stack. The encapsulation layer 1510a, 1510b, and 1510c may be formed by the use of one or more of PVD, CVD, FCVD, and spin-on coating processes. In some embodiment. The encapsulation layer 1510a, 1510b, and 1510c may include silicon nitride, silicon oxide, and aluminum oxide.

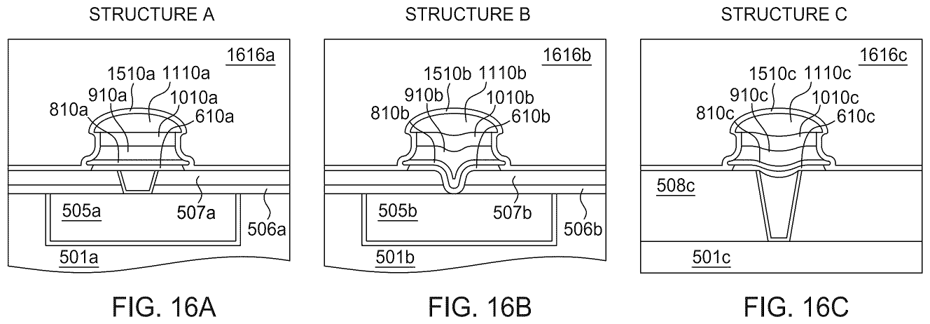

At block 455, as shown in FIGS. 16A, 16B, and 16C the ReRam etch process sequence includes an inter-layer dielectric (ILD) fill 1616a, 1616b, and 1616c over the encapsulation layer 1510a, 1510b, and 1510c in preparation for the formation of a top via at block 460. The inter-layer dielectric (ILD) fill 1616a, 1616b, and 1616c maybe formed of any suitable dielectric material, such as silicon dioxide (SiO₂) or silicon nitride (Si₂N₂).

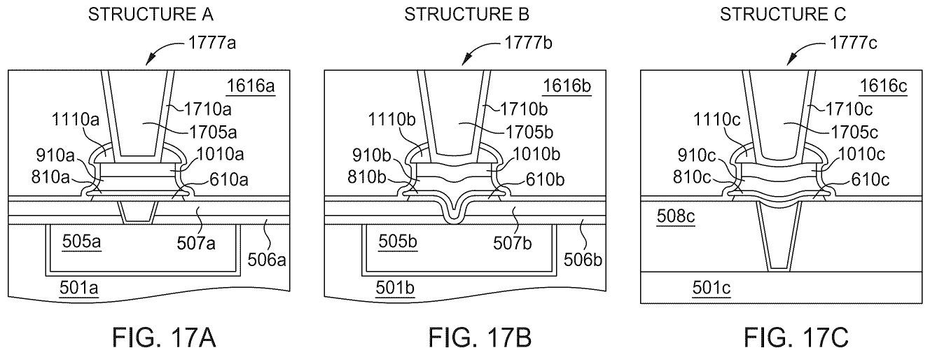

At block 460, as shown in FIGS. 17A, 17B, and 17C corresponding to structures A, B, and C, respectively, a via 1777a, 1777b, and 1777c to the top electrode 1010a, 1010aa, 1010b, 1010bb, 1010c, 1010cc is formed. In one embodiment, the via 1777a, 1777b, and 1777c comprises tantalum nitride lined copper. In one example, the via 1777a, 1777b, and 1777c can be formed by use of conventional through-silicon via (TSV) etching process, such as a “Bosch” etching process that can include a multi-step etching process, which can include a cyclic first isotropic etching step using a plasma generated halide containing gas (e.g., SF6) and a second passivation layer deposition step.

As described above, the methods described in this ReRam stack etch process sequence provide a single etch recipe to etch a complex ReRam stack, such as the TiN/TaOx-TaNx-TaOx/HfOx/Ru/TiN stack described in method 430. In one or more embodiments, the etch recipe described herein features high conductance and a symmetric chamber for radical driven process. By using a process gas mixture that includes a chlorine containing gas (e.g., a diatomic chlorine (Cl₂) gas, nitrogen (N₂), and oxygen (O₂) gas mixture) a desired tapered profile from top to bottom as well as no sidewall residue that can short the sidewalls of dielectric films located between metal films, is achieved. Moreover, avoiding the inclusion of chlorine during sidewall oxidation enhances reliability, prevents defects, and reduces the risk of premature dielectric breakdown at the sidewalls, thereby maintaining the integrity of the ReRam stack.

Typically, resistive memory cells with electrodes and graded films of very different selectivity are usually etched at very high temperatures, require ion milling, and/or multiple etch steps to target specific materials within the stack (i.e., to adjust chemistries). Beneficially, this disclosure provides an elegant and effective method to fabricate and etch a complex ReRam stack with improved lateral etch control, no sidewall shorting, and high throughput.

While the foregoing is directed to embodiments of the present disclosure, other and further embodiments of the disclosure may be devised without departing from the basic scope thereof, and the scope thereof is determined by the claims that follow.

What is claimed is:

1. A method for preparing a resistive memory cell comprising:
forming a resistive memory cell stack, comprising:
depositing a bottom electrode layer over a substrate, wherein the bottom electrode layer comprises TiN, TaN, Ru, or combinations thereof;
depositing a switching layer in contact with the bottom electrode layer in the presence of an oxygen containing gas;
depositing a TaOx oxygen exchange layer in contact with the switching layer;
depositing a top electrode layer over the TaOx oxygen exchange layer, wherein the top electrode layer is in contact with the TaOx oxygen exchange layer; and
etching the resistive memory cell stack, comprising:
performing an etching operation to form at least a portion of the resistive memory cell, wherein the etching operation is performed through a patterned hardmask layer positioned over the top electrode layer;
oxidizing sidewalls of one or more layers within the resistive memory cell stack, wherein the sidewalls are formed during the etching operation; and
forming an encapsulation layer over the at least a portion of the resistive memory cell.

2. The method of claim 1, further comprising:
performing an interlayer dielectric fill over the encapsulation layer; and
forming a top via through the encapsulation layer and the interlayer dielectric fill to the top electrode layer.

3. The method of claim 1, wherein the depositing the bottom electrode layer, the depositing the switching layer, the depositing the TaOx oxygen exchange layer, and the depositing the top electrode layer comprise physical vapor deposition processes, and the physical vapor deposition processes comprise the use of a single processing chamber without exposing the substrate to atmosphere.

4. The method of claim 1, further comprising performing a precleaning process on an exposed portion of the bottom electrode layer prior to depositing the switching layer, wherein the precleaning is performed in-situ without exposing the substrate to the atmosphere.

5. The method of claim 1, wherein the switching layer comprises HfOx.

6. The method of claim 5, further comprising oxidizing the switching layer with ozone.

7. The method of claim 1, wherein the switching layer comprises TaOx.

8. The method of claim 1, wherein the top electrode layer comprises TiN or TaN.

9. The method of claim 1, wherein the hardmask layer comprises chromium (Cr), silver (Ag), Si3N4, SiO2, TiN, SiN, carbon (C) containing materials, or combinations thereof.

10. The method of claim 1, wherein the etching operation comprises undercutting the bottom electrode layer.

11. The method of claim 1, wherein the etching operation includes undercutting the top electrode layer.

12. The method of claim 1, wherein the oxidizing the sidewalls includes a selective oxidation of TiN, Hf, TaOx, TaNx, or combinations thereof.

13. The method of claim 2, wherein the interlayer dielectric fill comprises silicon dioxide (SiO₂) or Silicon Nitride (Si₃N₄).

14. The method of claim 1, further comprising planarizing the bottom electrode layer prior to depositing the switching layer.

15. A resistive memory device, comprising:
a bottom via coupled to a bottom electrode layer, wherein the bottom electrode layer is disposed over a substrate and wherein the bottom electrode layer comprises TiN, TaN, Ru, or combinations thereof;
a switching layer disposed over the bottom electrode layer;
a TaOx oxygen exchange layer disposed over the switching layer;
a top electrode layer disposed over the TaOx oxygen exchange layer;
an encapsulation layer disposed over the top electrode layer;
an interlayer dielectric fill disposed over the encapsulation layer; and
a top metal filled via coupled to the top electrode layer, wherein the top metal filled via is formed thorough the encapsulation layer and the interlayer dielectric fill.

16. The resistive memory device of claim 15, wherein the bottom via is filled with a metal fill material and wherein the metal fill material comprises tantalum nitride lined copper.

17. The resistive memory device of claim 15, wherein the switching layer comprises HfOx.

18. The resistive memory device of claim 15, wherein the switching layer comprises TaOx.

19. The resistive memory device of claim 15, wherein the top electrode layer comprises TiN or TaN.

20. The resistive memory device of claim 15, wherein the switching layer comprises one or more overhang features.
